(19) United States
(12) Patent Application Publication
(10) Pub. No.: US 2024/0014330 A1
(43) Pub. Date: Jan. 11, 2024

(54) SOLAR CELL, SOLAR MODULE AND METHOD OF PRODUCING A SOLAR CELL

(71) Applicant: HANWHA Q CELLS GMBH, Bitterfeld-Wolfen (DE)

(72) Inventors: Axel SCHWABEDISSEN, Bitterfeld-Wolfen (DE); Matthias JUNGHÄNEL, Bitterfeld-Wolfen (DE); Stefan PETERS, Bitterfeld-Wolfen (DE)

(21) Appl. No.: 18/043,280

(22) PCT Filed: Aug. 27, 2021
(86) PCT No.: PCT/DE2021/100719

§ 371 Date: Feb. 27, 2023

(30) Foreign Application Priority Data
Aug. 27, 2020 (DE) 10 2020 122 431.1

(51) Int. Cl. H01L 31/0216; H01L 31/18

(52) U.S. Cl. CPC H01L 31/02167; H01L 31/1868

(57) ABSTRACT

A solar cell having a rear layer stack, wherein the rear layer stack has the following layer sequence: an AlOx layer, a first SiNx layer, a second SiNx layer, an SiOxNy layer, a third SiNx layer and at least one further layer, selected from the group consisting of SiOxNy, SiOx, AlOx, AINx and AlF. The invention further relates to a solar module comprising the solar cell, and a method of producing the solar cell, wherein the rear layer stack is deposited on a substrate in a tubular PECVD system with a boat as a substrate holder.

### RELATED APPLICATIONS

The present application is a National Phase entry of PCT Application No. PCT/DE2021/100719, filed Aug. 27, 2021, which claims priority to German Patent Application No. 10 2020 122 431.1, filed Aug. 27, 2020, the disclosures of which are hereby incorporated by reference herein in their entirety.

### FIELD OF THE INVENTION

The invention relates to a solar cell, to a solar module, and to a process for producing a solar cell. More particularly, the invention relates to a solar cell having a rear layer stack, to a solar module comprising a solar cell of this kind, and to a process for producing a solar cell of this kind.

### BACKGROUND OF THE INVENTION

A solar cell has a front side and a rear side, both of which can have layer stacks. The front side is a side that faces the incident light when the solar cell is in operation, whereas the rear side faces away from the incident light when in operation.

DE 10 2018 108 158 A1 discloses a solar cell in which is arranged, on a substrate of the solar cell, a rear layer stack consisting of an AlOx layer, a first SiNx layer, a second SiNx layer, a SiOxNy layer, and a third SiNx layer in that order. This rear layer stack has a higher Jsc (short-circuit current density) and higher FF (fill factor) compared to a rear layer stack consisting of an AlOx layer and layers solely of pure SiNx. There is however an ongoing need for a solar cell having optimized efficiency.

### SUMMARY

It is an object of the invention to provide a solar cell and a solar module, and also a process for producing a solar cell, in which the solar cell has optimized efficiency.

According to the invention, the object is achieved by a solar cell having the features of the claims, a solar module having the features of the claims, and a process having the features of the claims. Advantageous developments and modifications are specified in the dependent claims.

The invention relates to a solar cell having a rear layer stack, the rear layer stack having the following layer sequence: an AlOx layer, a first SiNx layer, a second SiNx layer, a SiOxNy layer, a third SiNx layer, and at least one further layer selected from the group consisting of SiOxNy, SiOx, AlOx, AlNx, and AlF.

The passivating effect of the layer stack according to the invention is improved compared to the passivating effect of the layer stack disclosed in DE 10 2018 108 158 A1. Thus, in the solar cell according to the invention there may be a gain in Voc (Voc=open-circuit voltage or no-load voltage) of up to approx. 1 mV compared to the solar cell according to DE 10 2018 108 158 A1. The third SiNx layer has a paste on the rear side, such as an aluminum screen-printing paste, to produce metalization on the rear side of the solar cell during production of the cell, and in order for this to be further optimized in respect of optics and also with regard to possible “metal pinning”, i.e. undesired direct contact of the paste, through the layer stack, with a substrate of the solar cell, the solar cell disclosed in DE 10 2018 108 158 is provided with at least one further layer that constitutes a dielectric layer.

A gain in efficiency of up to 0.12% was observed. Voc and/or Jsc will be improved. Without being bound to this theory, it is assumed that the reason for this is both improved reflection in the infrared spectral range, i.e. at wavelengths in the range of 900-1200 nm, alongside a simultaneous reduction in “metal pinning”, i.e. in the effective metalization of the substrate surface. One reason for the improved efficiency is therefore likely to be the improved utilization of light in the infrared spectral range when the solar cell is in operation. At the same time, it is assumed that the further layer has greater compatibility with a metal paste for producing a rear-side metalization, since the metal paste and furnace processes do not lead to (partial) destruction of this rear-side passivation or to direct contact of the metal paste with the substrate surface, i.e. to an undesirable increase in the area of the substrate surface in which the paste and substrate materials form a eutectic system.

A consequence of the process by which SiNx and SiOxNy layers are produced, for example in the PECVD (plasma-enhanced chemical vapor deposition) process, is that hydrogen becomes intercalated during the deposition of the layers, i.e. the SiNx layer or SiOxNy layer becomes hydrogenated, which is indicated by the designation SiNx:H layer or SiOxNy layer:H layer. The hydrogen contained in such a layer passivates recombination centers at the SiNx/Si interface or SiOxNy interface and in the bulk of the substrate. This has a positive effect on the efficiency of the solar cell.

Production of the rear layer stack of the invention is possible in a PECVD system in a process without aeration or a change of system. This can save on costs. It is preferable when all layers of the rear side stack are deposited by means of a direct plasma in a tubular PECVD system having a boat as substrate holder. However, it is also possible to deposit the AlOx by means of atomic layer deposition (ALD) or microwave remote plasma, and to deposit the SiNx and SiOxNy layers in a tubular PECVD system. The solar cell is preferably a mono- or polycrystalline solar cell having a silicon substrate. The solar cell is preferably a PERC cell (passivated emitter and rear cell).

The layers of the rear layer stack are arranged one above the other in the layer sequence indicated above. The rear layer stack may have further layers arranged between or on top of the layers mentioned above. Preferably, the rear layer stack constitutes a rear passivation layer stack of the solar cell. The rear passivation layer stack preferably consists of the layers mentioned above. It should however be noted that rear-side metalization may continue to be present at the rear of the solar cell.

The AlOx layer is preferably arranged on a substrate of the solar cell. Preferably, the AlOx layer is arranged directly on the substrate, i.e. without an additionally produced intermediate layer. It is however possible for an intermediate layer that is not additionally produced to be present between the AlOx layer and the substrate. For example, a SiOx layer having a layer thickness of for example 1 to 2 nm may be present at an interface between the AlOx layer and a Si wafer as the substrate. For example, this layer is already present, in the form of a native oxide, on the Si wafer before coating with the AlOx layer, or it forms during and/or after coating with the AlOx layer.

The first SiNx layer is arranged on a side of the AlOx layer facing away from the substrate, the second SiNx layer is arranged on a side of the first SiNx layer facing away from the substrate, the SiOxNy layer is arranged on a side of the second SiNx layer facing away from the substrate, the third SiNx layer is arranged on a side of the SiNxOy layer facing away from the substrate, and the at least one further layer is arranged on a side of the third SiNx layer facing away from the substrate, the layers preferably being arranged directly one above the other, i.e. without intermediate layers. In this embodiment, the rear side of the solar cell has the following structure: AlOx layer/first SiNx layer/second SiNx layer/SiOxNy layer/third SiNx layer/the at least one further layer. The at least one further layer is preferably a single layer or is alternatively preferably formed from two layers.

The respective SiNx and SiOxNy layers may differ in their refractive index or have the same refractive index. They preferably have different refractive indices.

In a preferred embodiment, the at least one further layer has a refractive index that differs from the refractive index of the third SiNx layer. Preferably, the refractive index of the at least one further layer is lower than the refractive index of the third SiNx layer. This achieves improved (total) reflection at the rear side of the solar cell. Preferably, the refractive index of the third SiNx layer is in the range from 2.0 to 2.4 and the refractive index of the at least one further layer is less than 2.0 or in the range from 1.5 to 1.6, in each case measured according to DIN at a wavelength of 632 nm.

It is advantageous when a refractive index of the first SiNx layer is greater than a refractive index of a second SiNx layer. The refractive index of the third SiNx layer is preferably lower than the refractive index of the first SiNx layer. More preferably, the refractive index of the third SiNx layer is equal to or essentially equal to the refractive index of the second SiNx layer. It is advantageous when a refractive index of the SiOxNy layer is lower than a refractive index of the first, second, and third SiNx layers.

Preferably, the refractive index of the AlOx layer is in the range from 1.55 to 1.65, the refractive index of the first SiNx layer is in the range from 2.1 to 2.4, the refractive index of the second SiNx layer is in the range of 1.9 to 2.1 and/or the refractive index of the SiOxNy layer is in the range from 1.5 to 1.8. Refractive indices mentioned in this application are in each case measured according to DIN at a wavelength of 632 nm.

In a preferred embodiment, the at least one further layer has a layer thickness in each case in the range from 10 to 60 nm or 20 to 50 nm. In a preferred embodiment, the AlOx layer has a layer thickness in the range from 5 to 20 nm. The first SiNx layer has a layer thickness preferably in the range from 20 to 40 nm, while the second SiNx layer has a layer thickness preferably in the range from 10 to 30 nm. The third SiNx layer has a layer thickness preferably in the range from 5 to 50 nm. The SiOxNy layer has a layer thickness preferably in the range from 40 to 120 nm. In the range of these values, the solar cell has high light coupling and a high passivating effect is achieved.

The at least one further layer is preferably a single AlOx layer. The AlOx layer preferably has a refractive index in the range from 1.55 to 1.65. It is alternatively preferable when the at least one further layer is a double-layer system, of which one layer is an SiOxNy layer and the other layer is an AlOx layer. It is alternatively preferable when the double-layer system consists of an AlNx layer and an AlFx layer.

The at least one further layer is more preferably a single SiOxNy layer. The advantage of the SiNxOy layer is that, during the production of the solar cell, it can after deposition of the third SiNx layer be deposited by adding just one further process gas such as N2O or O2 to the process gases SiH4 and NH3 required for deposition of the third SiNx layer. This makes it possible to produce the solar cell inexpensively.

In a preferred embodiment, a total layer thickness is in the range from 190 to 240 nm or 200 to 230 nm when the at least one layer consists of one layer. Preferably, the total layer thickness is in the range from 220 to 320 nm or 230 to 280 nm when the at least one layer consists of two layers. These configurations achieve a higher open-circuit voltage and higher efficiency both when light is incident from the front side and when light is incident from the rear side.

The solar cell may be a monofacial solar cell. Monofacial solar cells are only able to utilize, i.e. convert into electrical energy, light incident on their front side. Alternatively, the solar cell may be a bifacial solar cell. A bifacial solar cell is a solar cell that can utilize sunlight incident from two sides. The bifacial solar cell is able to utilize not just direct light coming in via the front side, but also direct or indirect light coming in via the rear side, the latter for example in the form of reflected sunlight. This allows the bifacial solar cell to achieve higher efficiency than in the case of a monofacial solar cell. For example, light reflected from a light house wall can be utilized from the rear side of the bifacial solar cell. Monofacial solar cells are however less costly than bifacial solar cells. The solar cell according to the invention is preferably a monofacial solar cell.

The invention relates also to a solar module that comprises a solar cell according to one or more of the embodiments described above. The efficiency of the solar module is increased through integration of the solar cell. The solar module can be bifacial or monofacial in design. In the latter case, bifacial solar cells too may be arranged in a solar module that is actually used for monofacial generation of electricity.

A bifacial solar module has the characteristic feature of being able to utilize both light incident on the front side and light incident on the rear side to generate electricity. In the bifacial solar module, a transparent film or glass is used as a rear-side encapsulation element. This makes it possible to utilize light that passes unused through the module and light reflected from the surroundings on the rear side. A monofacial solar module has the characteristic feature of being able to utilize only light incident on the front side to generate electricity. In the case of a monofacial solar module, a substantially opaque rear-side encapsulation element having a transmission of less than 2% is used. The solar module according to the invention is preferably a monofacial solar module.

The invention relates also to a process for producing a solar cell, wherein the rear layer stack is deposited on a substrate in a tubular PECVD system with a boat as substrate holder.

All layers are preferably deposited in the same tube, each being deposited one after the other by means of a plasma process optimized for the respective layer in respect of process gases, process pressure, plasma power and process temperature.

In the tubular PECVD system, a plurality of substrates is deployed in the same boat. In the boat, for example a graphite boat, two substrates are in each case arranged opposite one other and have different polarity. The boat has a plurality of support plates arranged parallel to one another for supporting the plurality of substrates during coating, the support plates being insulated from one another and alternately connected to terminals of an AC voltage generator (not shown). The support plates have a suitable holder (not shown), for example substrate pockets, holding pins or the like to hold the substrates, the individual substrates being held in the holding device at a distance from one another such that gases are able to flow through all intermediate spaces as evenly as possible and the formation of a plasma between the substrates to ensure uniform coating of the substrates is made possible.

### BRIEF DESCRIPTION OF THE DRAWINGS

Further characteristic features and advantages of the invention are illustrated with reference to the figures and described below by way of example. In the figures, which are schematic and not to scale:

FIG. 1 shows a partial cross-sectional view of a solar cell according to the invention;

FIG. 2 shows a partial cross-sectional view of another solar cell according to the invention; and

FIG. 3 shows a cross-sectional view of a tubular PECVD system in which a process for producing the solar cell is carried out.

### DETAILED DESCRIPTION

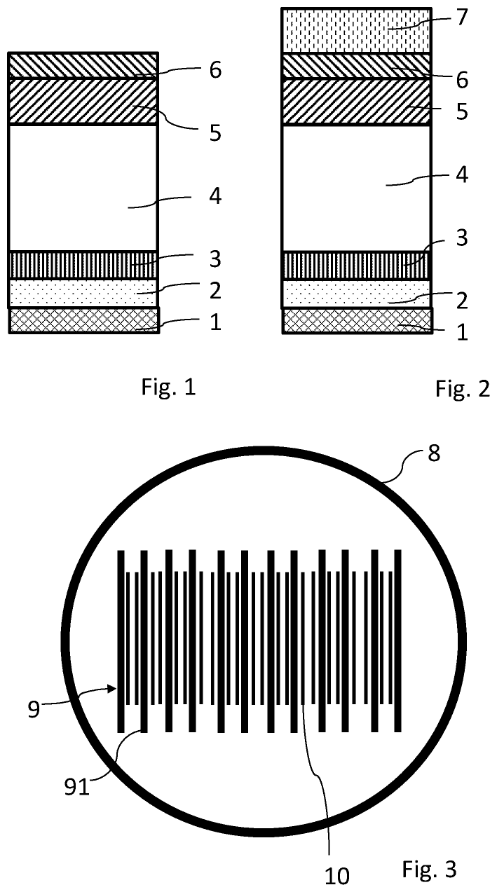

FIG. 1 shows a partial cross-sectional view of a solar cell according to the invention. Only the rear layer stack of the solar cell is shown. The layer stack is applied on the rear side of a substrate (not shown) and has the following layer sequence:
an AlOx layer 1 arranged on the substrate (not shown),
a first SiNx layer 2 arranged on a side of the AlOx layer 1 facing away from the substrate,
a second SiNx layer 3 arranged on a side of the first SiNx layer 2 facing away from the substrate,
a SiOxNy layer 4 arranged on a side of the third SiNx layer facing away from the substrate,
a third SiNx layer 5 arranged on a side of the SiOxNy layer 4 facing away from the substrate, and
a further layer 6 arranged on a side of the third SiNx layer 5 facing away from the substrate, the further layer 6 being a SiNxOy layer.

The AlOx layer 1 has a refractive index of 1.60 and a layer thickness of 15 nm. The first SiNx layer 2 has a refractive index in the region of 2.10 and a layer thickness in the region of 20 nm. The second SiNx layer 3 has a refractive index of 2.02 and a layer thickness in the region of 20 nm. The SiOxNy layer 4 has a refractive index of 1.60 and a layer thickness of 100 nm. The third SiNx layer 5 has a refractive index in the region of 2.02 and a layer thickness in the region of 30 nm. The further layer 6 has a refractive index of 1.60 and a layer thickness of 20 nm. The total layer thickness of the rear layer stack is 205 nm.

FIG. 2 shows a partial cross-sectional view of another solar cell according to the invention. The solar cell shown in FIG. 2 corresponds to the solar cell shown in FIG. 1, with the difference that a further layer 7 is arranged on the further layer 6. The further layer 7 is an AlOx layer having a refractive index of 1.60 and a layer thickness of 30 nm. The total layer thickness is 235 nm.

FIG. 3 shows a cross-sectional view of a tubular PECVD system in which a process for producing the solar cell is carried out. In the tubular PECVD system 8, a plurality of substrates 10 is deployed in the same boat 9. In the boat 9, two substrates 10 are in each case arranged opposite one other and have different polarity. The boat 9 has a plurality of support plates 91 arranged parallel to one another for supporting the plurality of substrates 10 during coating, the support plates 91 being insulated from one another and alternately connected to terminals of an AC voltage generator (not shown). The support plates 91 have a suitable holder (not shown), for example substrate pockets, holding pins or the like to hold the substrates 10, the individual substrates 10 being held in the holding device at a distance from one another such that gases are able to flow through all intermediate spaces as evenly as possible and the formation of a plasma between the substrates 10 to ensure uniform coating of the substrates 10 is made possible.

In the process for producing the solar cell shown in FIG. 1 or 2, the rear layer stack is in each case deposited on the substrates 10 in the tubular PECVD system 8 with the boat 9 as substrate holder in the following layer sequence: an AlOx layer, a first SiNx layer, a second SiNx layer, a SiOxNy layer, a third SiNx layer, and the at least one further layer selected from the group consisting of SiOxNy, SiOx, AlOx, AlNx, and AlF. These layers are applied one after the other in the same tubular PECVD system 8. The gas connections of the tubular PECVD system 8 and the deaeration and aeration feeds are omitted for clarity.

### LIST OF REFERENCE NUMERALS

1 AlOx layer
2 first SiNx layer
3 second SiNx layer
4 SiOxNy layer
5 third SiNx layer
6 further layer
7 further layer
8 tubular PECVD system
9 boat
91 support plate
10 substrate

1. A solar cell, comprising:
a rear layer stack having the following layer sequence: an AlOx layer, a first SiNx layer, a second SiNx layer, a SiOxNy layer, a third SiNx layer, and at least one further layer selected from the group consisting of SiOxNy, SiOx, AlOx, AlNx, and AlF.

2. The solar cell as claimed in claim 1, wherein the at least one further layer has a refractive index that differs from a refractive index of the third SiNx layer.

3. The solar cell as claimed in claim 2, wherein the refractive index of the at least one further layer is lower than the refractive index of the third SiNx layer.

4. The solar cell as claimed in claim 3, wherein the refractive index of the third SiNx layer is in a range from 2.0 to 2.4 and the refractive index of the at least one further layer is less than 2.0 or in a range from 1.5 to 2.0, in each case measured according to DIN at a wavelength of 632 nm.

5. The solar cell as claimed in claim 1, wherein the AlOx layer has a refractive index in a range from 1.55 to 1.65, the first SiNx layer has a refractive index in a range from 2.1 to 2.4, the second SiNx layer has a refractive index in a range from 1.9 to 2.1 and/or the SiOxNy layer has a refractive index in a range from 1.5 to 1.8, in each case measured according to DIN at a wavelength of 632 nm.

6. The solar cell as claimed in claim 1, wherein the at least one further layer has a layer thickness in each case in a range from 10 to 60 nm or 15 to 40 nm.

7. The solar cell as claimed in claim 1, wherein the at least one further layer is a SiOxNy layer or the at least one further layer is an AlOx layer or the at least one further layer is a SiOxNy layer and an AlOx layer or the at least one further layer is a AlNx layer and an AlFx layer.

8. The solar cell as claimed in claim 1, wherein the rear layer stack has a total layer thickness in a range from 190 to 240 nm or 200 to 230 nm when the at least one layer consists of one layer, and/or the rear layer stack has a total layer thickness in a range from 220 to 320 nm or 230 to 280 nm when the at least one layer consists of two layers.

9. A solar module comprising at least one solar cell as claimed in claim 1.

10. A process for producing a solar cell as claimed in claim 1, wherein the rear layer stack is deposited on a substrate in a tubular PECVD system with a boat as substrate holder.
